(19) United States
(12) Patent Application Publication
(10) Pub. No.: US 2011/0128686 A1
(43) Pub. Date: Jun. 2, 2011

(54) THIN FILM ENERGY FABRIC WITH ENERGY TRANSMISSION/RECEPTION LAYER

(75) Inventor: WYLIE MORESHEAD, BAINBRIDGE ISLAND, WA (US)

(73) Assignee: KINAPTIC, LLC, EVERGREEN, CO (US)

(21) Appl. No.: 12/962,443

(22) Filed: Dec. 7, 2010

Related U.S. Application Data
(63) Continuation-in-part of application No. 11/972,577, filed on Jan. 10, 2008.
Application No. 11/972,577 is a continuation-in-part of application No. 11/439,572, filed on May 23, 2006, now Pat. No. 7,494,945.
Application No. 11/439,572 is a continuation-in-part of application No. 12/390,209, filed on Feb. 20, 2009.
Application No. 12/390,209 is a continuation of application No. 11/439,572, filed on May 23, 2006, now Pat. No. 7,494,945.
(60) Provisional application No. 60/684,890, filed on May 26, 2005.

(51) Int. Cl. H05K 7/00

(52) U.S. Cl. 361/679.01

(57) ABSTRACT

The Thin Film Energy Fabric includes an energy storage section adapted to store electrical energy; an energy release section coupled to the energy storage section and configured to receive electrical energy from the energy storage section and to utilize the electrical energy; and an energy recharge section, coupled to the energy storage section, adapted to receive or collect energy and convert the received or collected energy to electrical energy either for storage by the energy storage section or for use by the energy release section or simultaneous storage in the energy storage section and immediate use by the energy release section. The energy release section can provide electrical energy transmission capability to charge devices which are placed in a position juxtaposed to a surface of the Thin Film Energy Fabric.

### CROSS-REFERENCE TO RELATED APPLICATIONS

This Application is a Continuation-In-Part of U.S. Patent application Ser. No. 11/972,577 filed on Jan. 10, 2008, which is a Continuation-In-Part of U.S. patent application Ser. No. 11/439,572 filed on May 23, 2006, now U.S. Pat. No. 7,494,945 B2 issued Feb. 24, 2009, which claims the benefit of U.S. Provisional Patent Application No. 60/684,890 filed on May 26, 2005. This Application also is a Continuation-In-Part of U.S patent application Ser. No. 12/390,209 filed on Feb. 20, 2009, which is a Continuation-In-Part of U.S. patent application Ser. No. 11/439,572 filed on May 23, 2006, now U.S. Pat. No. 7,494,945 B2 issued Feb. 24, 2009, which claims the benefit of U.S. Provisional Patent Application No. 60/684,890 filed on May 26, 2005. This application also is related to an application titled “Thin Film Energy Fabric With Light Generation Layer” and filed on the same date hereof; and to an application titled “Thin Film Energy Fabric With Self-Regulating Heat Generation Layer” and filed on the same date hereof; and to an application titled “Thin Film Energy Fabric For Self-Regulating Heated Wound Dressings” and filed on the same date hereof. The above-referenced patent applications and patent are incorporated herein by reference in their entirety.

### FIELD OF THE INVENTION

The present Thin Film Energy Fabric is directed to thin, flexible material and, more particularly, to a flexible fabric having electrical energy storage, electrical energy release, and electrical energy transmission/reception capabilities integrally formed therewith.

### BACKGROUND OF THE INVENTION

Presently, there are materials that incorporate energy releases in the form of light or heat and are powered by some external, rigid power source. However, there is not a single fabric available to the engineer or designer that has the electrical energy storage aspect directly integrated into it and is still thin, flexible, and can be manufactured into a product with the same ease as conventional fabrics. Hence, there is a need in this day and age for such a fabric that also has all of the normal characteristics of a modern engineered fabric, such as waterproof, breathability, moisture wickability, stretch, color, and texture choices. So far, no fabric has emerged with all of these characteristics.

### BRIEF SUMMARY OF THE INVENTION

The Thin Film Energy Fabric With Energy Transmission/Reception Layer (termed “Thin Film Energy Fabric” herein) has all of the characteristics of a modern engineered fabric, such as water resistance, waterproof, moisture wickability, breathability, stretch, and color and texture choices, along with the ability to store electrical energy and release it to provide a use of the stored electrical energy. In addition, the Thin Film Energy Fabric can include a section that takes energy from its surroundings, converts it to electrical energy, and stores it inside the Thin Film Energy Fabric for later use.

In particular, the Thin Film Energy Fabric includes an energy storage section adapted to store electrical energy; an energy release section coupled to the energy storage section and configured to receive electrical energy from the energy storage section and to utilize the electrical energy; and an energy recharge section, coupled to the energy storage section, adapted to receive or collect energy, typically in a wireless manner, and convert the received or collected energy to electrical energy either for storage by the energy storage section or for use by the energy release section or simultaneous storage in the energy storage section and immediate use by the energy release section. The energy release section can provide electrical energy transmission capability to charge devices which are placed in a position juxtaposed to a surface of the Thin Film Energy Fabric.

The Thin Film Energy Fabric can include optional treatment and sealing and optional protective and decorative sections. It should be noted that these various sections can be arranged coplanar or layered as long as the sections are continually connected or enveloped together. In addition, the fabric may include one or more properties of semi-flexibility or flexibility, water resistance or waterproof, and formed as a thin, sheet-like material or a thin woven fabric. The Thin Film Energy Fabric can be formed from strips of material having the characteristics described above and that are woven together to provide a thin, flexible material.

### BRIEF DESCRIPTION OF THE DRAWINGS

The foregoing and other features and advantages of the present Thin Film Energy Fabric will be more readily appreciated as the same become better understood from the following detailed description when taken in conjunction with the accompanying drawings, wherein:

FIG. 1 is an isometric illustration of the present Thin Film Energy Fabric;

FIG. 2 is an isometric illustration of another embodiment of the present Thin Film Energy Fabric;

FIG. 3 is an isometric illustration of a further embodiment of the present Thin Film Energy Fabric;

FIG. 4 is an isometric illustration of yet another embodiment of the present Thin Film Energy Fabric showing energy flow into and out of the fabric;

FIG. 5 illustrates embedded electronic components in film substrates;

FIGS. 6 and 7 illustrate two batten-forming adhesive patterns;

FIG. 8 illustrates the use of registration points in assembling components of energy textile panels; and

FIG. 9 illustrates a typical wireless apparatus for the transfer of energy into and out of the Thin Film Energy Fabric.

### DETAILED DESCRIPTION OF THE INVENTION

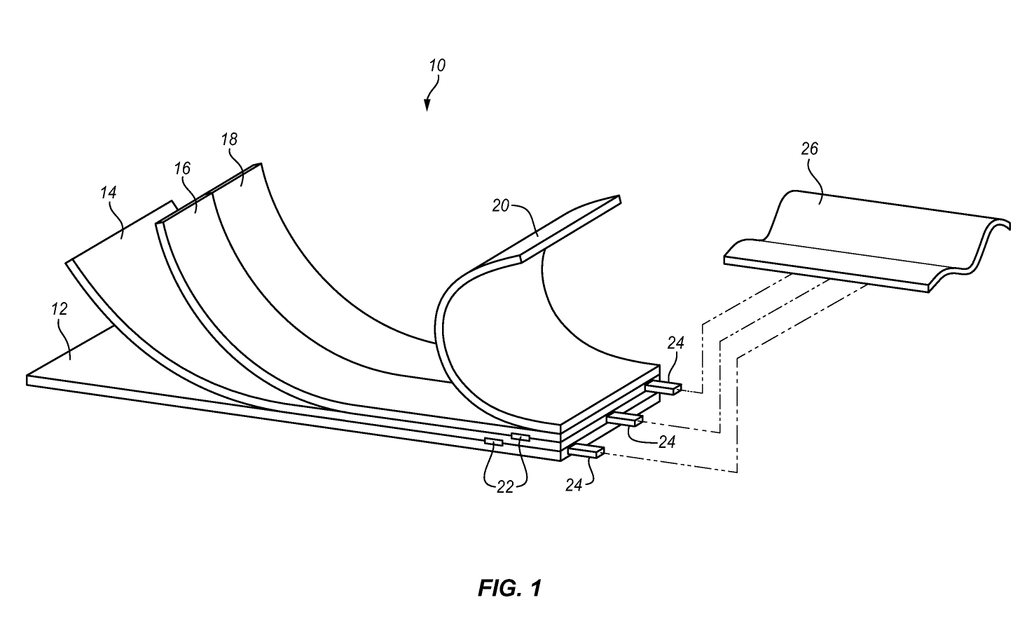

FIG. 1 illustrates the flexible sheet form of the finished Thin Film Energy Fabric 10 that includes an energy release section 12 and an energy storage section 14. An optional charge section 16 or recharge section 18 or combination thereof is shown along with an optional protective section 20 that also can be a decorative section. These sections can be manufactured separately and then laminated together, or each section can be directly deposited on the one beneath it, or a combination of both techniques can be employed to produce the final Thin Film Energy Fabric 10. These sections can be arranged in any order including coplanar arrangements, layers, planes, and other stacking arrangements, and there can be multiple instances of each section in the final Thin Film Energy Fabric 10.

The sections also can have different embodiments on the same plane. For instance, a section of the charge or recharge plane 16, 18 can use photovoltaics while another section can use piezoelectrics, or a section of the energy release plane can produce light while another section can produce heat. Similarly, one section of the plane can produce light while another section on the same plane can use photovoltaics to recharge the energy storage section. Some sections must be connected electrically to some of the other sections. This can be done with the contact occurring at certain points 22 directly between the sections or with the contact occurring through leads 24 that connect via a Printed Circuit Board 26 which is either integrated into the Thin Film Energy Fabric 10 or located external to the Thin Film Energy Fabric 10, thus providing operator input, monitoring, and control capabilities. Although not required, this Printed Circuit Board 26 can be built on a flexible substrate as can the leads 24, and the Printed Circuit Board 26 can simultaneously control multiple separate Thin Film Energy Fabric instances. Briefly, controls such as fixed and variable resistance, capacitance, inductance, and combinations of the foregoing, as well as software and firmware embodied in corresponding hardware, can be implemented to regulate voltage and current, phase relationships, timing, and other known variables that ultimately affect the output. Regulation can be user controlled or automatic or a combination of both.

The leads 24 that connect the sections can, but do not have to, be connected to the Printed Circuit Board 26. All lead connections should be sealed at the point of contact to provide complete electrical insulation. The flexible Printed Circuit Board 26, which contains circuits, components, switches, and sensors, also can be integrated directly into the final fabric as another section, coplanar or layered, and so can the leads.

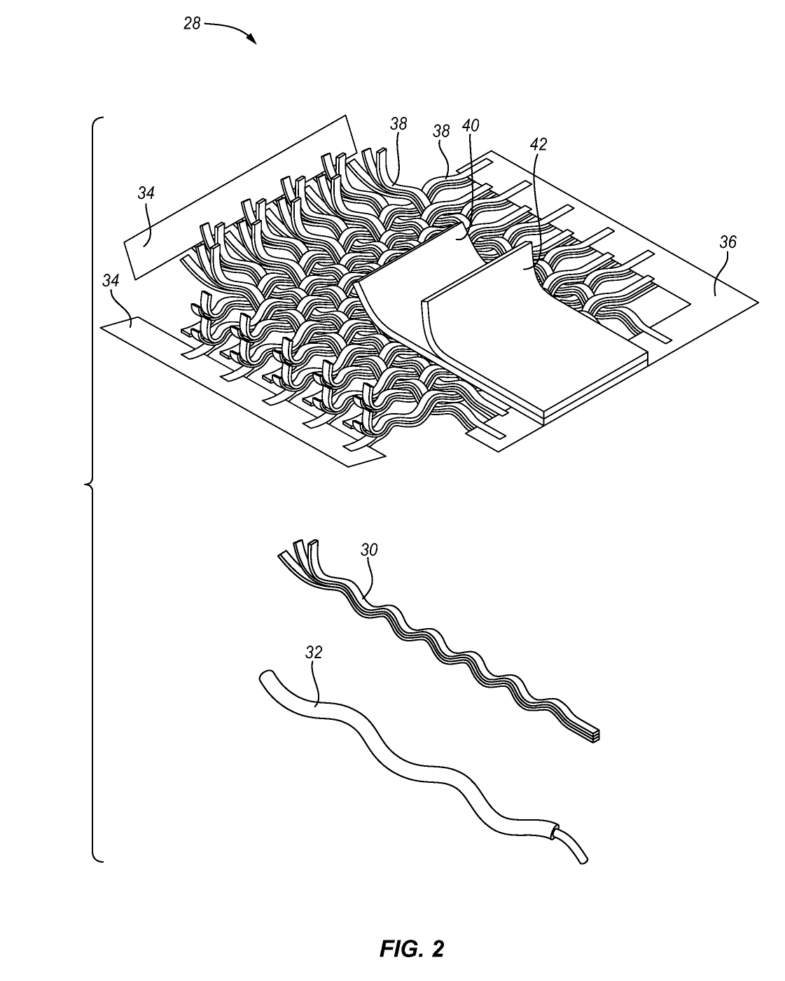

FIG. 2 illustrates the highly flexible woven form of a finished energy fabric 28 that includes woven strips 30 where each individual strip contains an energy release section, an energy storage section, and an optional charge/recharge section. The strips 30 would not necessarily need to be constructed with rectangular sections; they also can be constructed with coaxial sections 32. The strips 30 can, but not all of them would have to, be electrically connected at the edge 34 of the fabric 28 with similar contacts 36 on the warp and weft of the weave being isolated at the same potential as applicable for the circuit to function. All of the strips 30 do not necessarily have to have the same characteristics. For instance, strips with different energy release embodiments can be woven into the same piece of fabric as shown at 38.

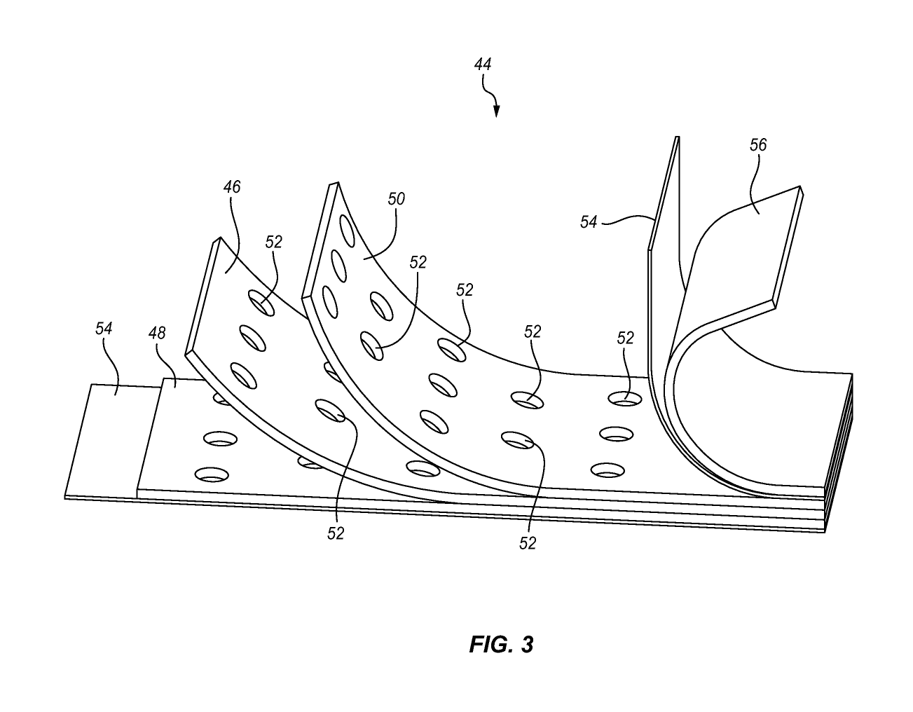

FIG. 3 illustrates a highly flexible sheet 44 consisting of an energy storage section 46, an energy release section 48, and an optional charge or recharge section 50, all patterned with openings 52 to impart traits such as breathability and flexibility to the final fabric. These openings or holes 52 in the fabric 44 can be deposited in a pattern for each section, with the sections then laminated together such that the patterns line up to provide an opening through the fabric covered only by a treatment or sealing enveloping section 54, and possibly a decorative or protective section 56; or the fabric 44 can have holes 52 cut into it after lamination but before the application of the treatment or sealing section 54 or the decorative or protective section 56 or both. It should be noted that these holes 52 can be of any shape.

The treatment or sealing section (54) can be deposited or adhered onto and envelope one or both sides of the final fabric 44 to facilitate the waterproof and breathability properties of the fabric 44. This section keeps liquid water from passing through the section but allows water vapor and other gases to move through the fabric section freely. The optional decorative or protective section 56 also can be added to one or both sides of the fabric 44 to change external properties of the final fabric such as texture, durability, or moisture wickability. As with the fabric embodiments in FIGS. 1 and 2, the sections can have different embodiments on the same plane. For instance, a section of the charge or recharge section 50 can use photovoltaics while another section can use piezoelectrics, or a section of the energy release plane can produce light while another section can produce heat. Similarly, one section of the plane can produce light while another section on the same plane can use photovoltaics to recharge the energy storage section. The sections also can be arranged in any order including coplanar arrangements as well as stacking arrangements, and there can be multiple instances of each section in the final fabric.

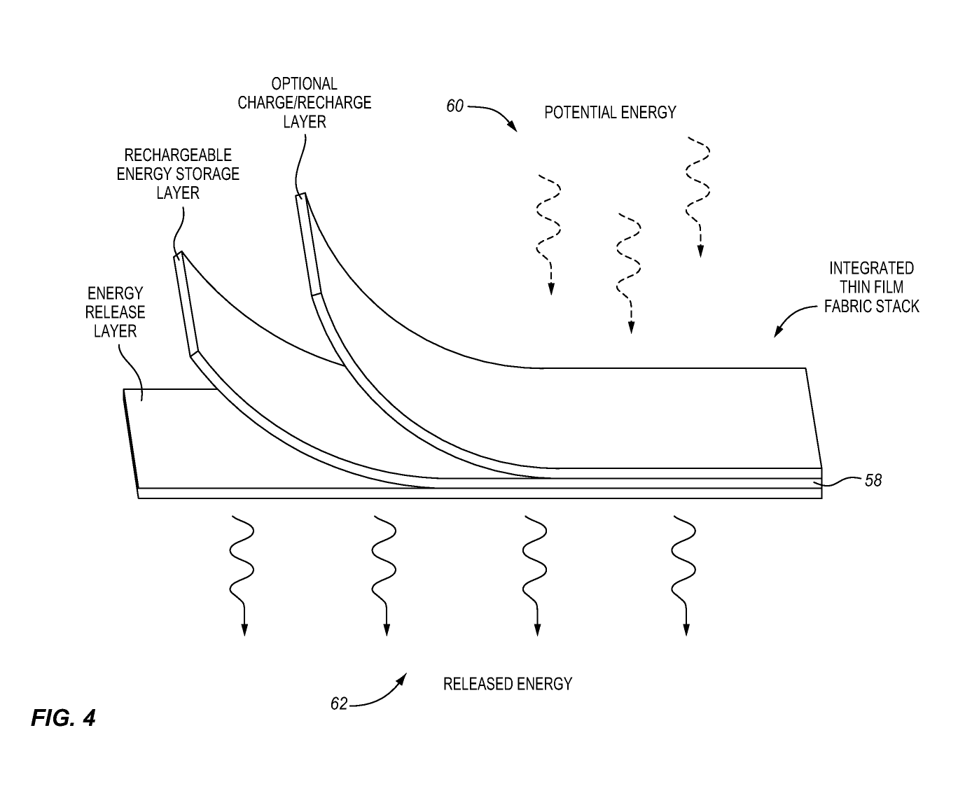

FIG. 4 illustrates a flexible, integrated fabric 58 capable of receiving surrounding energy 60 from many possible sources, converting it to electrical energy and storing it integral to the fabric, and then releasing the electrical energy in different ways 62.

### Thin Film Energy Fabric Manufacturing

One method of manufacturing the individual sections into a custom, energized textile panel would consist of: 1) locating the energy storage, energy release, and possibly energy recharge sections adjacent to or on top of one another (depending on panel layout and functionality); 2) electrically interconnecting the various sections by affixing thin, flexible circuits to them that would provide the desired functionality; and 3) laminating this entire system of electrically integrated sections between breathable, waterproof films. The preferred materials in the heating embodiment of a panel would consist of lithium polymer for the energy storage section, Positive Temperature Coefficient heaters for the energy release section, piezoelectric film for the recharge section, copper traces deposited on a polyester substrate for the thin, flexible electrical interconnects, and a high Moisture Vapor Transmission Rate polyurethane film as the encapsulating film or protective section. While cloth material can be used, preferably it would be laminated over the encapsulant film. The cloth could be any type of material and would correspond to the decorative section as described herein. The type of cloth would completely depend on the desired color, texture, wickability, and other characteristics of the exterior of the panel.

### Energy Storage Layer

A thin film, lithium ion polymer battery is an ideal flexible thin, rechargeable, and electrical energy storage section. These batteries consist of a thin film anode layer, cathode layer, and electrolytic layer; and each battery forms a thin, flexible sheet that stores and releases electrical energy and is rechargeable. Carbon nanotubes can be used in conjunction with the lithium polymer battery technology to increase capacity and would be integrated into the final fabric in the same manner as would a standard polymer battery. It should be noted that the energy storage section should consist of a material whose properties do not degrade with use and flexing. In the case of lithium polymers, this generally means the more the electrolyte is plasticized, the less the degradation of the cell that occurs with flexing.

Another technology that can be used for the energy storage section is a supercapacitor or ultracapacitor which use different technologies to achieve a thin, flexible, rechargeable energy storage film and are good examples in the ultra- and super-capacitor industry as to what is currently available commercially for integration and use in this Thin Film Energy Fabric.

Thin film micro fuel cells of different types (PEM, DFMC, solid oxide, MEMS, and hydrogen) can be laminated into the final fabric to provide an integrated power source to work in conjunction with (hybridized), or in place of, a thin film battery or thin film capacitor storage section.

### Energy Release Layer

In the energy release section, there are several embodiments including, but not limited to, heating, cooling, light emission, and energy transmission.

The above-described architecture includes the use of a wireless charging circuit as the energy release section, where the wireless charging circuit interfaces with an external device as described below to wirelessly transmit power, as supplied by the energy storage section of the Thin Film Energy Fabric, to the external device. Thus, an external device, such as a wireless communication device (for example, a cellular phone) or media player or laptop (or notebook) computer or the like, can be placed on or juxtaposed to the Thin Film Energy Fabric, where the presence of the external device is automatically sensed by the energy release section to initiate the wireless energy transfer from the energy storage section of the Thin Film Energy Fabric to the external device. The proper mating of these two devices can be ensured via the use of a mutual wireless communication frequency as noted below. As an alternative to the wireless transmission of the electrical power stored in the energy storage section, a wired connector or leads 24 can be used as the transfer mode, such that the Thin Film Energy Fabric provides a reserve power source for an interconnected external device.

For the heating embodiment, a normal thin wire or etched thin film resistance heater works well. A Positive Temperature Coefficient resistive heater also works very well for a thin film, self-regulating, heater section. In the case of the Positive Temperature Coefficient resistive heater, its heater is built to regulate itself specifically to a temperature determined before manufacture. This means that the resistive heating element changes its resistance depending on the instantaneous temperature of the heater without the use of sensors and added circuitry. All these heating elements are deposited on a thin flexible substrate, usually kapton or polyester, which then can be laminated with or without an adhesive to the other fabric sections; or the heating elements can be directly deposited on an adjoining fabric section. For instance, the heater element can be deposited directly on the packaging layer of a lithium polymer battery and then covered with a thin film of polyester, kapton, urethane, or some other thin flexible material to encapsulate and insulate the heating element and/or fabric section.

For the cooling embodiment of the energy release section, a thin film, superlattice, thermoelectric cooling device as well as a Negative Temperature Coefficient material is ideal for integration into the final fabric. Being a thin film device, it can be deposited using another of the fabric sections as its substrate or it can be deposited on a separate substrate and then laminated with or without an adhesive to the other existing fabric sections.

For the light-emitting embodiment of the energy release sections, there are many organic polymer-based thin film technologies available for integration into the fabric. Organic light emitting diodes (OLEDs) are polymer-based devices that are manufactured in thin, flexible, sheet form and can be powered directly from a DC power source without an inverter. Some other examples of applicable organic, flexible, light-emitting technologies that use DC power without an inverter include polymeric light emitting diodes (PLEDs), light emitting polymers (LEPs), and flexible liquid crystal displays (LCDs). The light-emitting embodiment of the fabric can be used to display a static lit design or a changing pixilated display. Being thin film devices, all of these technologies can be deposited using another of the fabric sections as their substrate or they can be deposited on separate substrates and then laminated with or without adhesives to the other existing fabric sections.

Charge and Recharge Layers

There are many options currently available for the charge and recharge section in its several embodiments. In the case that the embodiment is using light energy to charge or recharge the energy storage section, flexible photovoltaic cells can be used. In the case that the embodiment is using fabric flexure and piezoelectric materials to generate electricity for storage in the energy storage section, films that are easily laminated and electrically integrated into the final fabric can be used. In the case that the embodiment is using an inductive or wireless charging system to produce electrical energy for storage, the system can be laminated and electrically integrated into the final fabric.

Wireless energy transfer or wireless power transmission is the process that takes place in any system where electrical energy is transmitted from a power source to an electrical load without interconnecting wires. Wireless transmission is useful in cases where instantaneous or continuous energy transfer is needed but interconnecting wires are inconvenient, hazardous, or impossible. There are a number of wireless transmission techniques, and the following description characterizes several for the purpose of illustrating the concept.

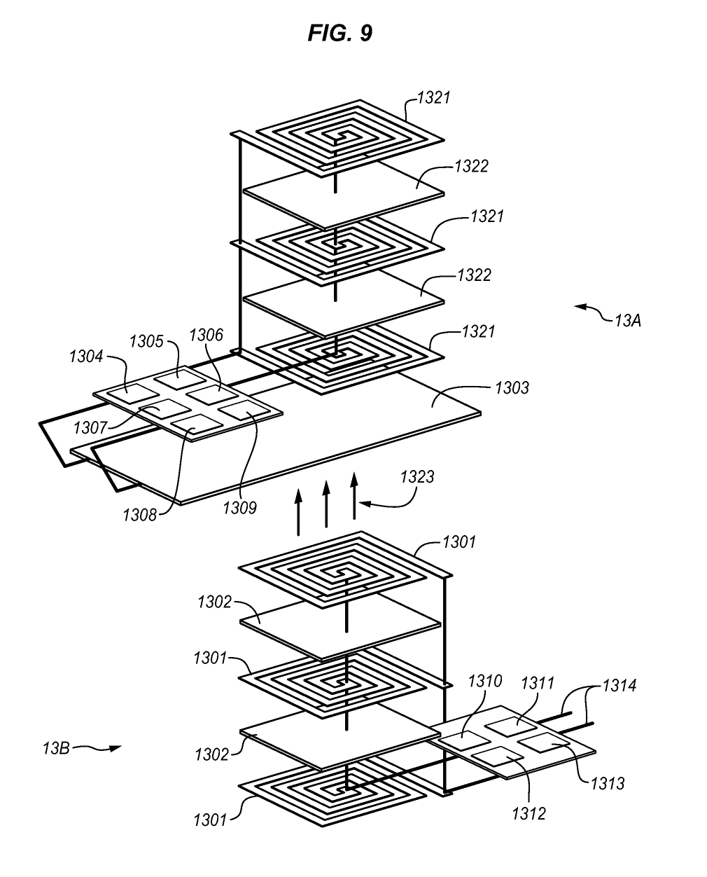

Inductive charging uses the electromagnetic field to transfer energy between two objects. A charging station sends energy through inductive coupling to an electrical device, which stores the energy in the batteries. Because there is a small gap between the two coils, inductive charging is one kind of short-distance wireless energy transfer. When resonant coupling is used, the transmitter and receiver inductors are tuned to a mutual frequency; and the drive current can be modified from a sinusoidal to a non-sinusoidal transient waveform. This has an added benefit in that it can be used to “key” specific devices which need charging to specific charging devices to insure proper matching of charging and charged devices. Thus, the Thin Film Energy Fabric can use multiple wireless power transmitters, as shown in FIG. 9, each tuned to a specific frequency appropriate for a selected external device that is to be wirelessly charged.

Induction chargers typically use an induction coil to create an alternating electromagnetic field from within a charging base station, and a second induction coil in the portable device takes power from the electromagnetic field and converts it back into electrical current to charge the battery. The two induction coils in proximity combine to form an electrical transformer.

The “electrostatic induction effect” or “capacitive coupling” is an electric field gradient or differential capacitance between two elevated electrodes over a conducting ground plane for wireless energy transmission involving high frequency alternating current potential differences transmitted between two plates or nodes. The electrostatic forces through natural media across a conductor situated in the changing magnetic flux can transfer energy to a receiving device.

The other kind of charging, direct wired contact (also known as “conductive charging” or “direct coupling”) requires direct electrical contact between the batteries and the charger. Conductive charging is achieved by connecting a device to a power source with plug-in wires, such as a docking station, or by moving batteries from a device to a charger.

It also should be noted that in the case of a thermoelectric (Peltier) or photoelectric (photovoltaic) section that is used as an energy release embodiment, this section can also be used in a reversible fashion as an energy recharging section for the energy storage section(s). For example, if a system is producing a large amount of excess heat energy, say in the case of a garment used during high aerobic activity, that heat energy can be converted by the thermoelectric section to electricity for storage in the energy storage section(s) and then can be used reversibly back through a thermoelectric section for heating when there is an absence of heat after the aerobic activity has stopped. The same sort of energy harvesting technique could be used by the photoelectric (photovoltaic) sections to produce light when there is an absence of it and also to transform the light energy to electrical energy for storage in the energy storage sections when there is an excess of it. In the case of the piezoelectric embodiment, electrical energy can be created and stored during flexing and then used reversibly to stiffen the piezoelectric section if a stiffening of the fabric is required.

As shown in FIG. 9, the wireless power receiver 13A and wireless power transmitter 13B are each constructed from multiple layers of Flexible Printed Circuit (FPC) coils 1321 and 1301, respectively, which are each separated by magnetic cores 1322 and 1302, respectively, (preferably soft magnetic cores). These magnetic cores 1322, 1302 function to increase the field strength (range/power). A battery 1303 stores the electrical energy in the wireless power receiver 13A. A voltage conversion circuit interfaces the FPC coils 1321 with the battery 1303 (which can be the energy storage section 14) and comprises a voltage regulator 1304, resonance capacitor 1305, tuning circuit 1306, and charging/protection circuit 1307, which operate in well-known fashion to output a controlled voltage at port 1308 once the presence of a wireless charging transmitter is detected by the charging pad sense circuit 1309. In the wireless power transmitter 13B, a resonant circuit, which includes resonance capacitor 1310, signal conditioning circuit 1311, and tuning circuit 1312, operates to output an energy field 1323 to wireless power receiver 13A. In response to chargeable device sense circuit 1313 detecting the presence of a wireless power receiver 13A (such as the energy recharge section 18), the wireless power transmitter 13B converts the power received from power main 1314 to a wireless signal 1323 output via FPC coils 1301 to the wireless power receiver 13A (such as the energy recharge section 18).

### Protective Layers

There are many products available that can be used for the protective and decorative section(s) that are engineered for next-to-skin wickability, fibrous, fleece-type comfort, water repellency, specific color, specific texture, and many other characteristics that can be incorporated by laminating that section into the final fabric. There are also many ThermoPlastic Urethanes (TPUs) available for use as sealing and protective envelopes. These materials exhibit very high Moisture Vapor Transmission Ratios (MVTRs) and are extremely waterproof allowing the assembled energy storage, release, and recharge sections to be enveloped in a highly breathable, waterproof material that also provides a high degree of protection and durability. In addition to the TPUs, which are a solid monolithic structure, there are also microporous materials that are available for use as breathable, waterproof sealing and protective envelopes. This microporous technology is commonly found in Gore products and also can be used in conjunction with TPUs. It should also be noted that when laminating these breathable waterproof envelopes around the assembled sections, care must be taken, whether one is using an adhesive or not, to maintain the breathability of the laminate. If adhesive is being used, this adhesive must also have breathable characteristics. The same should be said for a laminate process that does not use adhesive. Whatever the adhesion process is, it needs to maintain the breathability and waterproof property of the enveloping protective section providing these are traits deemed necessary for the final textile panel.

An optional treatment or sealing section 40 can be deposited on one or both sides of the final fabric 28 to facilitate the waterproof and breathability properties of the fabric. This enveloping section keeps liquid water from passing through but allows water vapor and other gases to move through it freely. An optional protective or decorative section 42 also can be added to change external properties of the final fabric such as texture, durability, stretchability, or moisture wickability.

### Embedding Electronic Components in Film Substrates Summary

The present Thin Film Energy Fabric also provides techniques for sealing devices, such as electronic circuits, components, and electrical energy storage devices inside a highly flexible, robust laminate panel for subsequent integration into a larger system. This Thin Film Energy Fabric provides a system where the devices, such as electronic circuits, components, and energy storage devices, are embedded between laminated film substrates to form a flexible, environmentally sealed, finished laminate able to be integrated into a larger system such as a garment or accessory. The embedded circuits, components, and energy storage devices can be included in many different substrate layers within the finished laminate. The devices also can be located in separate panels and connected together via external connectors to provide a larger system. It is possible to produce a finished laminate with environmentally sealed, embedded electrical components, circuits, and energy storage devices that is thin and flexible.

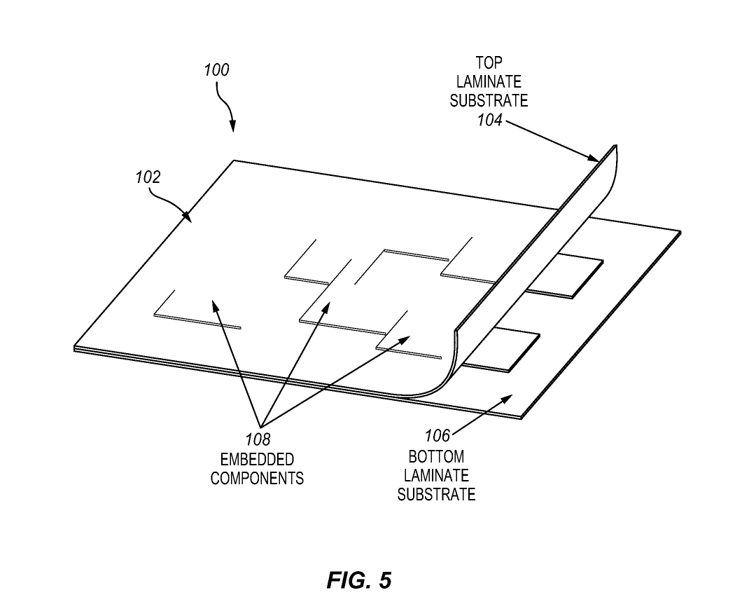

FIG. 5 shows a segment 100 of laminate material 102 having a top laminate layer 104 and a bottom laminate layer 106. Embedded between these two layers 104, 106 are devices 108, such as electrical circuits, electrical energy storage devices, electromagnetic devices, semiconductor chips, heating or cooling elements or both, light emission devices such as incandescent lights or LEDs or both, sensors, speakers, RF transceivers, antennae, and the like.

### Battened Adhesive Lamination Background

Currently, there are many substrate or layer adhesion systems that consist of solid or patterned adhesive applied to film for the purpose of affixing the film to another object. However, there is not an adhesion system coupled with a lamination manufacturing technique for producing a single laminate that maximizes adhesive strength between the films, maximizes the MVTR properties of the finished laminate, and maintains a robust fluid barrier for the electronic components embedded between its films.

The present Thin Film Energy Fabric provides a lamination system and technique that maximizes substrate film adhesion strength and maintains a robust fluid barrier for embedded electronic components while also maximizing MVTR through the finished laminate. By using striped adhesion on the substrate layers and orienting the layers during lamination so that the adhesive strips are at an angle other than parallel to one another, the present Thin Film Energy Fabric creates a finished single laminate that is strong, highly breathable, and retains a sectioned fluid barrier so embedded components are protected if the finished laminate is somehow compromised. This adhesion technique can be used with many layers of substrates to create a final laminate with many battened adhesive layers. The adhesion also can consist of a single or multiple patterned adhesive layers as long as the resultant adhesive pattern when laminated forms a closed adhesive batten.

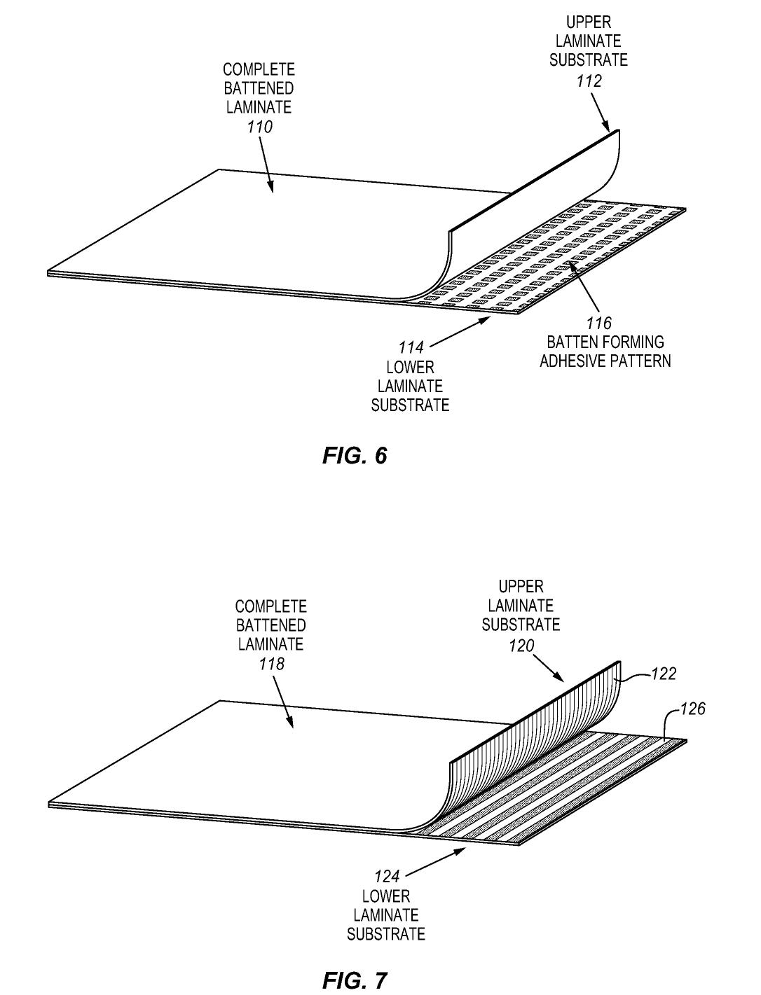

FIG. 6 shows a battened laminate section 110 with upper and lower substrates 112, 114, respectively, that are adhered together by a batten-forming adhesive pattern 116 that is shown on the lower laminate substrate 114. FIG. 7 shows a complete battened laminate section 118 in which an upper laminate substrate 120 has longitudinal strips of adhesive 122, and the lower laminate substrate 124 has transverse strips of adhesive 126. When these substrates 120, 124 are pressed together, the adhesive strips 122, 126 form a batten checkerboard pattern.

### Energized Textile Lamination Press Summary

While currently there are systems that can be used for the lamination of thin, flexible substrates around electronic circuits and components, there is no system capable of allowing an operator to place electronic circuits and components at registration points imparted to the film substrate and then initiate a lamination of the two films around the placed circuits and components to ensure no air bubbles are formed between the lamination films. The present Thin Film Energy Fabric provides a lamination system that allows the user to place devices, such as circuits and components, in a specific geometry between two film sections, panels, layers, or substrates while ensuring that no unwanted air is trapped between the laminations as the lamination occurs. The registration points can be transmitted to the substrate via light or via a physical jig that allows the embedded devices to be placed and held as the lamination process occurs.

To ensure that air bubbles are not trapped between the substrates or sections as the lamination process occurs, the contact surface of the press incorporates a curved or domed convex deformable surface that presses air out from a single location toward the current unsealed areas while not damaging components in the current laminated areas as the entire surface receives the pressure and possibly radiant energy required to continuously laminate the panel. The introduction of energized textile panels creates the need for specific manufacturing techniques and processes that enable energized fabric panels to be mass produced with a high degree of quality.

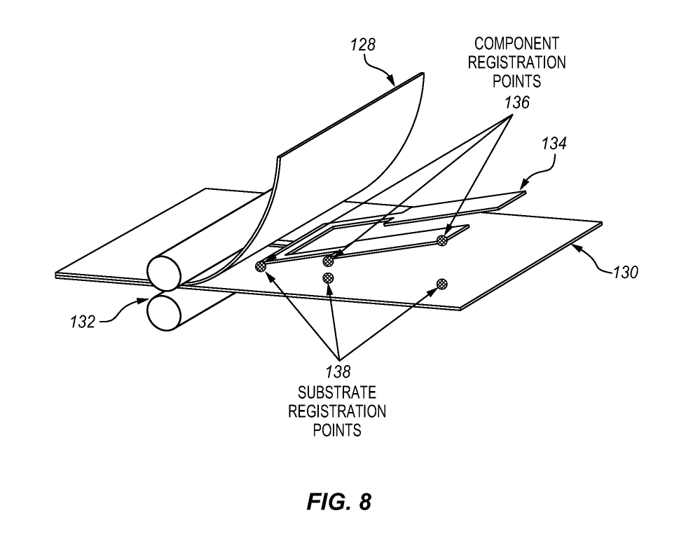

FIG. 8 illustrates one embodiment of the present disclosure in which upper and lower layers 128, 130, respectively, are compressed together between a pair of rollers 132. It is to be understood that a single roller pressing on a support surface could also be used. An electric component 134 is placed between the two layers 128, 130 and positioned by component registration points 136 and substrate registration points 138 as described above.

### SUMMARY

The Thin Film Energy Fabric includes an energy storage section adapted to store electrical energy; an energy release section coupled to the energy storage section and configured to receive electrical energy from the energy storage section and to utilize the electrical energy; and an energy recharge section, coupled to the energy storage section, adapted to receive or collect energy, typically in a wireless manner, and convert the received or collected energy to electrical energy either for storage by the energy storage section or for use by the energy release section or simultaneous storage in the energy storage section and immediate use by the energy release section. The energy release section can provide electrical energy transmission capability to charge devices which are placed in a position juxtaposed to a surface of the Thin Film Energy Fabric.

What is claimed as new and desired to be protected by Letters Patent of the United States is:

1. A Thin Film Energy Fabric with wireless energy transfer, comprising:
an energy storage section configured to store electrical energy;
an energy release section configured to utilize the electrical energy stored in the energy storage section comprising:
a wireless energy transfer circuit for transmitting electric power from said energy storage section to an external device via one of: inductive and wireless charging;
an energy recharge section adapted to collect energy from a source located external to said Thin Film Energy Fabric and convert the collected energy to electrical energy for storage by the energy storage section, for immediate use by the energy release section, or simultaneous storage in the energy storage section and use by the energy release section; and
wherein the energy storage and said energy recharge sections are encapsulated in a laminate to form a sheet-like material.

2. The Thin Film Energy Fabric with wireless energy transfer of claim 1 wherein said wireless energy transfer circuit comprises:
an external device detector for detecting the presence of a wireless power receiver in an external device.

3. The Thin Film Energy Fabric with wireless energy transfer of claim 2 wherein said wireless energy transfer circuit further comprises:
a resonant circuit, responsive to said external device detector detecting the presence of a wireless power receiver in an external device, for generating a wireless signal at a predetermined frequency.

4. The Thin Film Energy Fabric with wireless energy transfer of claim 1 wherein said energy release section comprises:
a plurality of resonant circuits, each generating a wireless signal at a predetermined frequency which differs from the predetermined frequency of other ones of said plurality of resonant circuits.

5. The Thin Film Energy Fabric with wireless energy transfer of claim 4 wherein said energy release section further comprises:
wherein each of said plurality of resonant circuits is responsive to said external device detector detecting the presence of a wireless power receiver in an external device, for generating a wireless signal at a predetermined frequency if said wireless power receiver is tuned to the predetermined frequency of the resonant circuit.

6. The Thin Film Energy Fabric with wireless energy transfer of claim 1 wherein:
the energy storage and energy release sections comprise first and second layers, respectively, and are arranged in at least one of: coplanar arrangements, layers, planes, and other stacking arrangements; and
there can be multiple instances of each section.

7. The Thin Film Energy Fabric with wireless energy transfer of claim 1 wherein said energy recharge section is coupled to at least the energy storage section and formed with the energy storage and energy release sections in the laminate.

8. The Thin Film Energy Fabric with wireless energy transfer of claim 1 wherein said energy recharge section comprises:
a wireless energy transfer circuit for receiving electric power from a source located external to said Thin Film Energy Fabric via one of: inductive and wireless charging.

9. The Thin Film Energy Fabric with wireless energy transfer of claim 1 wherein:
the energy storage, energy release, and energy recharge sections comprise first, second, and third layers, respectively, and are arranged in at least one of: coplanar arrangements, layers, planes, and other stacking arrangements; and
there can be multiple instances of each section.

10. The Thin Film Energy Fabric with wireless energy transfer of claim 1 wherein the energy storage and energy release sections are formed to be flexible and to have at least one of the following characteristics of breathability, moisture wickability, water resistance, waterproof, and stretchability.

11. A Thin Film Energy Fabric with wireless energy transfer, comprising:
an energy storage section configured to store electrical energy;
an energy release section configured to utilize the electrical energy stored in the energy storage section;
an energy recharge section adapted to collect energy from a source located external to said Thin Film Energy Fabric and convert the collected energy to electrical energy for storage by the energy storage section, for immediate use by the energy release section, or simultaneous storage in the energy storage section and use by the energy release section;
wherein the energy storage, energy release, and energy recharge sections are encapsulated in a laminate to form a sheet-like material.

12. The Thin Film Energy Fabric with wireless energy transfer of claim 11 wherein said energy recharge section comprises:
a wireless energy transfer circuit for receiving electric power from a source located external to said Thin Film Energy Fabric via one of: inductive and wireless charging.

13. The Thin Film Energy Fabric with wireless energy transfer of claim 12 wherein said wireless energy transfer circuit comprises:
an external device detector for detecting the presence of a wireless power transmitter in an external device.

14. The Thin Film Energy Fabric with wireless energy transfer of claim 13 wherein said wireless energy transfer circuit further comprises:
a voltage conversion circuit, responsive to said external device detector detecting the presence of a wireless power transmitter in an external device, for receiving a wireless signal from said wireless power transmitter at a predetermined frequency.

15. The Thin Film Energy Fabric with wireless energy transfer of claim 11 wherein said energy recharge section comprises:
a plurality of voltage conversion circuits, each receiving a wireless signal at a predetermined frequency which differs from the predetermined frequency of other ones of said plurality of resonant circuits.

16. The Thin Film Energy Fabric with wireless energy transfer of claim 15 wherein said energy recharge section further comprises:
wherein each of said plurality of voltage conversion circuits is responsive to said external device detector detecting the presence of a wireless power transmitter in an external device, for receiving a wireless signal at a predetermined frequency if said wireless power receiver is tuned to the predetermined frequency of the voltage conversion circuit.

17. The Thin Film Energy Fabric with wireless energy transfer of claim 11 wherein:
the energy storage and energy release sections comprise first and second layers, respectively, and are arranged in at least one of: coplanar arrangements, layers, planes, and other stacking arrangements; and
there can be multiple instances of each section.

18. The Thin Film Energy Fabric with wireless energy transfer of claim 11 wherein said energy recharge section is coupled to at least the energy storage section and formed with the energy storage and energy release sections in the laminate.

19. The Thin Film Energy Fabric with wireless energy transfer of claim 11 wherein:
the energy storage, energy release, and energy recharge sections comprise first, second, and third layers, respectively, and are arranged in at least one of: coplanar arrangements, layers, planes, and other stacking arrangements; and
there can be multiple instances of each section.

20. The Thin Film Energy Fabric with wireless energy transfer of claim 11 wherein the energy storage and energy release sections are formed to be flexible and to have at least one of the following characteristics of breathability, moisture wickability, water resistance, waterproof, and stretchability.
